(19) United States
(12) Patent Application Publication
(10) Pub. No.: US 2014/0151689 A1
(43) Pub. Date: Jun. 5, 2014

(54) DISPLAY APPARATUS AND METHOD OF MANUFACTURING DISPLAY APPARATUS

(71) Applicant: Panasonic Liquid Crystal Display Co., Ltd., Himeji-shi (JP)

(72) Inventor: Genshiro KAWACHI, Osaka (JP)

(73) Assignee: Panasonic Liquid Crystal Display Co., Ltd., Himeji-shi (JP)

(21) Appl. No.: 14/093,034

(22) Filed: Nov. 28, 2013

(30) Foreign Application Priority Data
Nov. 30, 2012 (JP) 2012-262234

(51) Int. Cl. H01L 27/12

(52) U.S. Cl. CPC H01L 27/124; H01L 27/1259
USPC 257/43; 438/34

(57) ABSTRACT

A display apparatus includes a gate electrode formed on a substrate as a portion of a gate line, a gate insulating film formed on the gate electrode, a semiconductor oxide layer formed on the gate insulating film, and a first insulating film formed to cover the semiconductor oxide layer. The display apparatus also includes a drain electrode connected to the semiconductor oxide layer through a first contact hole that is formed at the first insulating film, a second insulating film formed on the first insulating film, a third insulating film formed on the second insulating film, and a pixel electrode formed on the third insulating film. The pixel electrode is connected to the semiconductor oxide layer through a second contact hole that is formed on the semiconductor oxide layer.

### CROSS-REFERENCE TO RELATED APPLICATION

The present application claims priority from Japanese Applications JP2012-262234 filed on Nov. 30, 2012, the content of which is hereby incorporated by reference into this application.

### BACKGROUND OF THE INVENTION

1. Field of the Invention

The present invention relates to a display apparatus and a method of manufacturing a display apparatus.

2. Description of the Related Art

A display apparatus, which includes a thin film transistor (TFT) using a semiconductor oxide in a semiconductor layer, is known. In the display apparatus, the TFT is formed by sequentially stacking a gate insulating film, a semiconductor oxide layer, a channel protection film, and source/drain electrodes on a gate electrode that is formed as a portion of a gate line. Note that the source/drain electrodes are formed of the same metal layer, and are respectively connected to the semiconductor oxide layer through contact holes formed at the channel protection film (see JP Patent No. 4982619).

### SUMMARY OF THE INVENTION

Recently, a definition of a liquid crystal display apparatuses has become higher. However, for example, the presence of a source electrode for connecting a TFT and a pixel electrode may restrict the high definition of liquid crystal display apparatuses. Specifically, for example, since a predetermined area is required to form a contact hole for connecting a source electrode and a semiconductor layer, an aperture ratio of a pixel is reduced, thus increasing the power consumption of the entire display apparatus. Also, it is difficult to dispose a source electrode while keeping a predetermined distance between two adjacent signal lines. As a result it is impossible to reduce a pixel size.

In view of the above problem, an object of one or more embodiments of the present invention is to provide a display apparatus and a method of manufacturing a display apparatus, which can promote higher definition.

(1) In one or more embodiments of the present invention, a display apparatus includes a gate electrode formed on a substrate as a portion of a gate line, a gate insulating film formed on the gate electrode, a semiconductor oxide layer formed on the gate insulating film, and a first insulating film formed to cover the semiconductor oxide layer. The display apparatus also includes a drain electrode connected to the semiconductor oxide layer through a first contact hole that is formed at the first insulating film, a second insulating film formed on the first insulating film, a third insulating film formed on the second insulating film, and a pixel electrode formed on the third insulating film. The pixel electrode is connected to the semiconductor oxide layer through a second contact hole that is formed on the semiconductor oxide layer.

(2) In the display apparatus according to (1), the display apparatus further includes a common electrode between the second insulating film and the third insulating film, in a region facing the pixel electrode.

(3) In the display apparatus according to (2), the common electrode covers a drain line comprising the drain electrode, through the second insulating film.

(4) In the display apparatus according to (1), the second contact hole is formed at the first to third insulating films.

(5) In the display apparatus according to (1), the second insulating film is an organic protection film.

(6) In the display apparatus according to (1), the second contact hole is formed outside the gate electrode in a cross-sectional view.

(7) In the display apparatus according to (2), the display apparatus further includes a common signal line in a portion between the substrate and the gate insulating film. The common signal line is connected to the common electrode through a third contact hole.

(8) In the display apparatus according to (1), the display apparatus further includes a common electrode facing the pixel electrode, between the substrate and the gate insulating film.

(9) In the display apparatus according to (8), the display apparatus further includes a common signal line in a portion between the gate insulating film and the common electrode.

(10) In the display apparatus according to one of (7) to (9), the common signal line is disposed in a direction along the gate line.

(11) In one or more embodiments of the present invention, a method of manufacturing a display apparatus includes forming a gate electrode on a substrate as a portion of a gate line, forming a gate insulating film on the gate electrode, forming a semiconductor oxide layer on the gate insulating film, forming a first insulating film so as to cover the semiconductor oxide layer, forming a first contact hole at the first insulating film, forming an electrode connected to the semiconductor oxide layer through the first contact hole, forming a second insulating film on the first insulating film, forming a third insulating film on the second insulating film, forming a second contact hole on the semiconductor oxide layer, and forming a pixel electrode on the third insulating film. The pixel electrode is connected to the semiconductor oxide layer through the second contact hole.

(12) The display apparatus according to claim 1, wherein said gate electrode is in direct contact with said substrate.

(13) The display apparatus according to claim 12, wherein said gate insulating film is in direct contact with said gate electrode.

(14) The display apparatus according to claim 13, wherein said semiconductor oxide layer is in direct contact with said gate insulating film.

(15) The display apparatus according to claim 14, wherein said first insulating film is in direct contact with said semiconductor oxide layer.

(16) The display apparatus according to claim 15, wherein said second insulating film is in direct contact with said first insulating film.

(17) The display apparatus according to claim 16, wherein said pixel electrode is in direct contact with said third insulating film.

### BRIEF DESCRIPTION OF THE DRAWINGS

FIG. 1 is a schematic diagram illustrating a display apparatus according to an embodiment of the present invention;

FIG. 2 is a conceptual diagram illustrating a pixel circuit formed on a TFT substrate illustrated in FIG. 1;

FIG. 3 is a diagram illustrating an example of a configuration of a pixel illustrated in FIG. 2;

FIG. 4 is a diagram illustrating a schematic example of a IV-IV section of FIG. 3;

FIG. 5 is a diagram illustrating a schematic example of a V-V section of FIG. 3;

FIG. 6A is a schematic diagram illustrating a method of manufacturing a TFT substrate 102 illustrated in FIG. 1;

FIG. 6B is a schematic diagram illustrating a method of manufacturing a TFT substrate 102 illustrated in FIG. 1;

FIG. 6C is a schematic diagram illustrating a method of manufacturing a TFT substrate 102 illustrated in FIG. 1;

FIG. 6D is a schematic diagram illustrating a method of manufacturing a TFT substrate 102 illustrated in FIG. 1;

FIG. 7 is a diagram illustrating an example of a configuration of a pixel according to Modification 1;

FIG. 8 is a diagram illustrating a schematic example of a VIII-VIII section of FIG. 7;

FIG. 9 is a diagram illustrating a schematic example of a IX-IX section of FIG. 7;

FIG. 10 is a diagram illustrating an example of a configuration of a pixel according to Modification 2;

FIG. 11 is a diagram illustrating a schematic example of a XI-XI section of FIG. 10;

FIG. 12 is a diagram illustrating a schematic example of a XII-XII section of FIG. 10;

FIG. 13 is a diagram illustrating an example of a configuration of a pixel according to Modification 3;

FIG. 14 is a diagram illustrating a schematic example of a XIV-XIV section of FIG. 13; and

FIG. 15 is a diagram illustrating a schematic example of a XV-XV section of FIG. 13.

### DETAILED DESCRIPTION OF THE INVENTION

Hereinafter, embodiments of the present invention will be described with reference to the drawings. In the drawings, the same or similar elements are denoted by the same reference numerals, and the same or similar description thereof will be omitted.

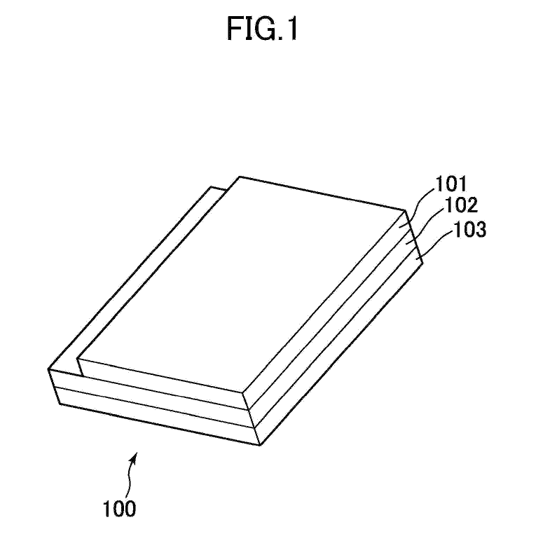

FIG. 1 is a schematic diagram illustrating a display apparatus according to an embodiment of the present invention. As illustrated in FIG. 1, for example, a display apparatus 100 includes a TFT substrate 102, in which a thin film transistor (TFT) and the like are formed, and a filter substrate 101 facing the TFT substrate 102 and including a color filter (not illustrated). Also, the display apparatus 100 includes a liquid crystal material (not illustrated) encapsulated in a region interposed between the TFT substrate 102 and the filter substrate 101, and a backlight unit 103 disposed to contact an opposite side of the TFT substrate 102 with respect to the filter substrate 101. Note that the configuration of the display apparatus 100 illustrated in FIG. 1 is just an example, and the present embodiment is not limited thereto.

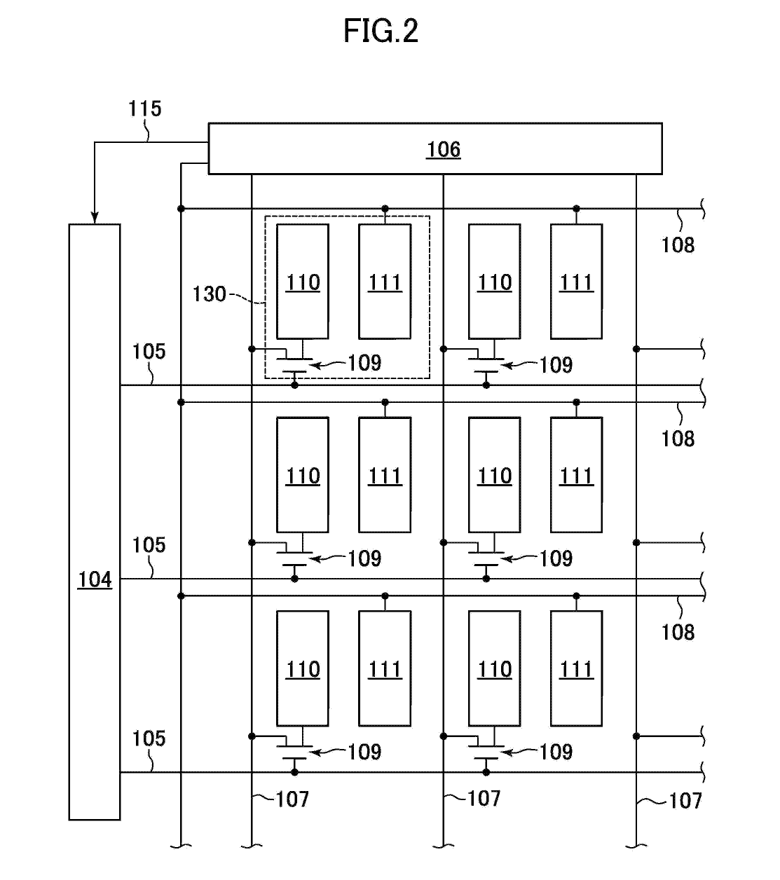

FIG. 2 is a conceptual diagram illustrating a pixel circuit formed on the TFT substrate 102 illustrated in FIG. 1. As illustrated in FIG. 2, the TFT substrate 102 includes a plurality of gate lines 105 disposed at substantially regular intervals in the horizontal direction of FIG. 2, and a plurality of drain lines 107 disposed at substantially regular intervals in the vertical direction of FIG. 2. Also, the gate lines 105 are connected to a shift register circuit 104, and the drain lines 107 are connected to a driver 106.

The shift register circuit 104 includes a plurality of basic circuits (not illustrated) corresponding respectively to the gate lines 105. Note that each of the basic circuits includes a plurality of TFTs or capacitors, and outputs a gate signal, which becomes a high voltage in a corresponding gate scan period (high-signal period) among a 1-frame period in response to a control signal 115 from the driver 106 and becomes a low voltage in the other period (low-signal period), to the corresponding gate line 105.

Each of pixels 130, which are partitioned in a matrix configuration by the gate lines 105 and the drain lines 107, includes a TFT 109, a pixel electrode 110, and a common electrode 111. Here, a gate of the TFT 109 is connected to the gate line 105, one of a source and a drain of the TFT 109 is connected to the drain line 107, and the other is connected to the pixel electrode 110. Also, the common electrode 111 is connected to a common signal line 108. Also, the pixel electrode 110 and the common electrode 111 are disposed to face each other.

Next, the summary of an operation of the above pixel circuit will be described. The driver 106 applies a reference voltage to the common electrode 111 through the common signal line 108. Also, under the control of the driver 106, the shift register circuit 104 outputs a gate signal to the gate of the TFT 109 through the gate line 105. Also, the driver 106 supplies an image signal voltage through the drain line 107 to the TFT 109, to which the gate signal is output, and the image signal voltage is applied to the pixel electrode 110 through the TFT 109. In this case, a potential difference is generated between the pixel electrode 110 and the common electrode 111.

Then, by controlling the potential difference, the driver 106 controls a light distribution of liquid crystal molecules of a liquid crystal material inserted between the pixel electrode 110 and the common electrode 111. Here, since light from the backlight unit 103 is guided to the liquid crystal material, the light distribution of the liquid crystal molecules can be controlled to control the amount of light of backlight unit 103, thereby displaying an image.

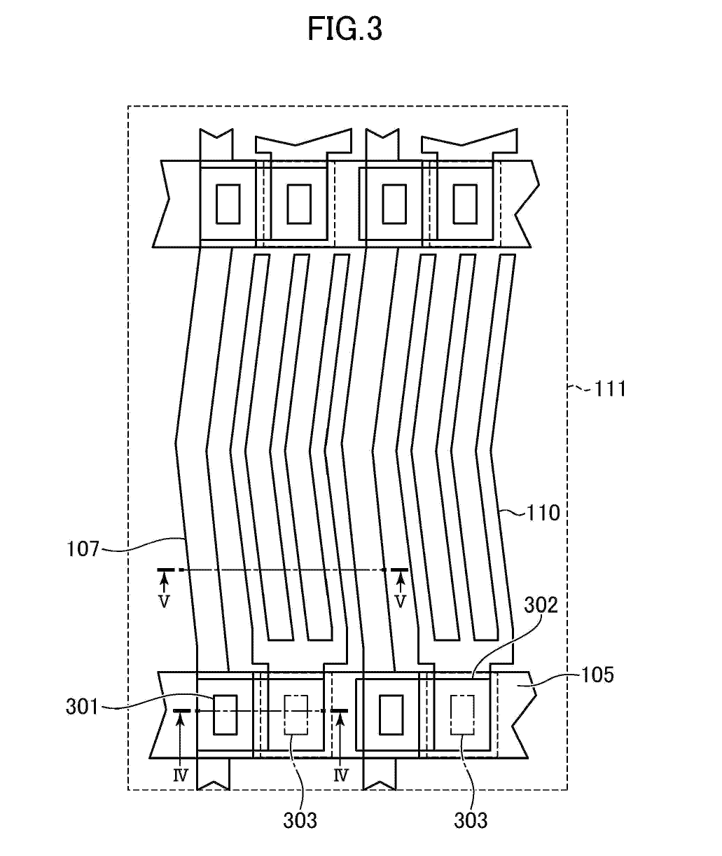

FIG. 3 is a diagram illustrating an example of a configuration of the pixel 130 illustrated in FIG. 2. Specifically, FIG. 3 illustrates an example of a plan view of the pixel 130. As illustrated in FIG. 3, as in the above, the pixel 130 includes a plurality of gate lines 105 disposed at substantially regular intervals in the horizontal direction and a plurality of drain lines 107 disposed at substantially regular intervals in the vertical direction of FIG. 2. The drain line 107 is connected to a semiconductor oxide layer 302 through a first contact hole 301 formed on the gate line 105. Note that the semiconductor oxide layer 302 is formed of, for example, InGaZnO.

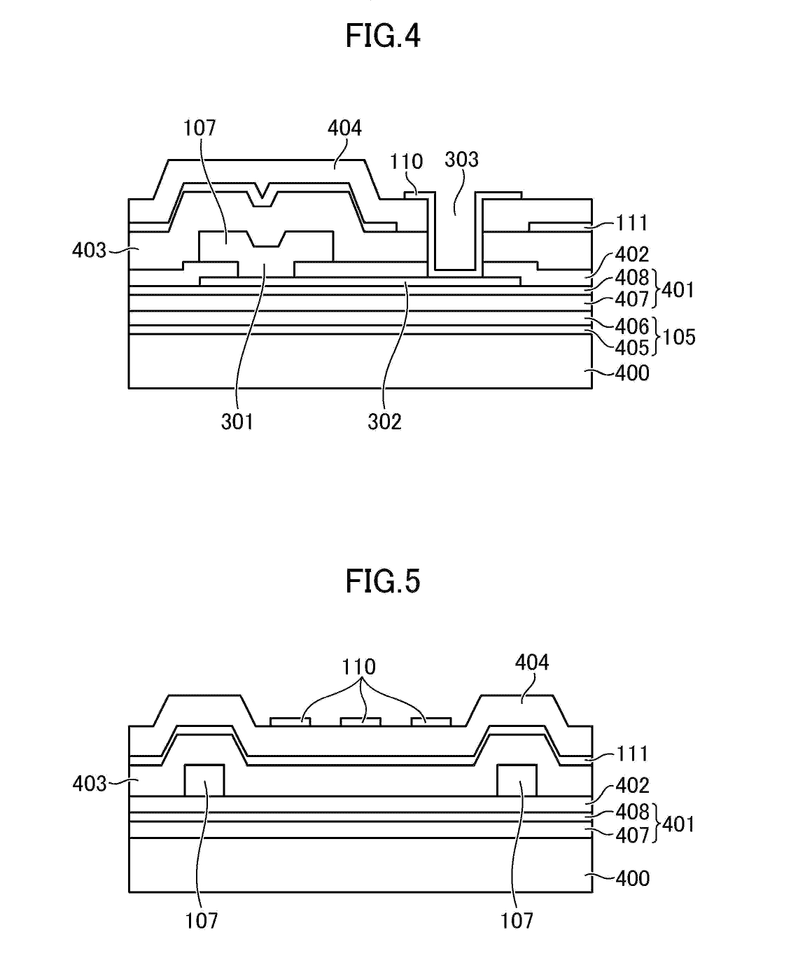

Also, a common electrode 111 is disposed to face a pixel electrode 110. As illustrated in FIG. 3, the pixel electrode 110 is formed in a pectinate shape, for example. Also, the shape of the pixel electrode 110 illustrated in FIG. 3 is just an example, and the present embodiment is not limited thereto. Also, one end of the pixel electrode 110 is connected to the semiconductor oxide layer 302 through a second contact hole 303 formed on the gate line 105. While the common electrode 111 is formed to almost cover the entire pixel, an opening portion is provided to surround the second contact hole 303, and the pixel electrode 110 and the semiconductor oxide layer 302 are connected to the opening portion. This will be described in detail with reference to FIG. 4.

FIG. 4 is a diagram illustrating an example of a IV-IV section of FIG. 3. As illustrated in FIG. 4, in a region in which the TFT 109 is formed, a gate electrode formed as a portion of the gate line 105, a gate insulating film 401, a semiconductor oxide layer 302, a first protective insulating film 402, a drain electrode formed as a portion of the drain line 107, a source electrode formed as a portion of the pixel electrode 110, a second protective insulating film 403, a common electrode 111, and an interlayer insulating film 404 are stacked on a substrate 400 sequentially from the bottom of FIG. 4.

A first contact hole 301 is formed at the first protective insulating film 402, and the drain electrode is connected to the semiconductor oxide layer 302 through the first contact hole 301.

A second contact hole 303 is formed at the first and second protective insulating films 402 and 403 and the interlayer insulating film 404, and the pixel electrode 110 is connected to the semiconductor oxide layer 302 through the second contact hole 303. Note that, as described above, a portion of the pixel electrode 110 connected to the semiconductor oxide layer 302 corresponds to a source electrode of the TFT 109. Also, between the second protective insulating film 403 and the interlayer insulating film 404, the common electrode 111 is formed to cover the drain line 107.

Note that, as illustrated in FIG. 4, the gate line 105 is formed, for example, by stacking a molybdenum layer 405 and a copper layer 406. Also, as illustrated in FIG. 4, the gate insulating film 401 is formed, for example, by stacking a silicon nitride (SiN) film 407 and a silicon oxide (SiO₂) film 408. Also, the first and second protective insulating films 402 and 403 are formed of, for example, SiO₂.

FIG. 5 is a diagram illustrating an example of a V-V section of FIG. 3. As illustrated in FIG. 5, for example, in a pixel region surrounded by the drain line 107 and the gate line 105, a gate insulating film 401, a first protective insulating film 402, a second protective insulting film 403, a common electrode 111, an interlayer insulating film 404, and a pixel electrode 110 are stacked on a substrate 400 sequentially from the bottom of FIG. 5.

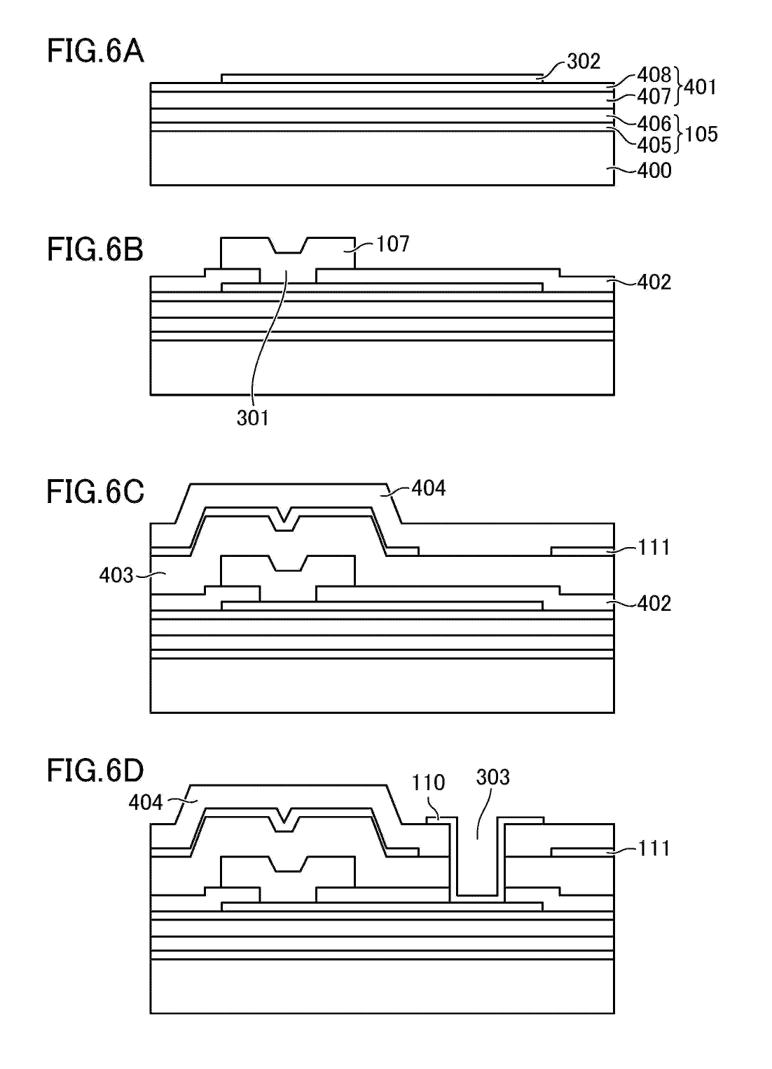

Next, a schematic example of a method of manufacturing the TFT substrate 102 according to an embodiment of the present invention will be described. FIG. 6 is a schematic diagram illustrating a method of manufacturing the TFT substrate 102 illustrated in FIG. 1.

As illustrated in FIG. 6A, a metal film forming a gate line 105 is deposited on a substrate 400, and the metal film is processed in a predetermined shape, thereby forming the gate line 105. Note that the metal film may have, for example, a two-layer structure of molybdenum and copper. Thereafter, a gate insulating film 401 and a semiconductor oxide layer 302 are stacked and processed in a predetermined shape.

Thereafter, as illustrated in FIG. 6B, a first protective insulating film 402 is deposited, and then a first contact hole 301 is formed. Then, a metal film forming a drain line 107 is deposited and patterned to form the drain line 107. Here, as illustrated in FIG. 6B, a first insulating film 402 is formed to cover the semiconductor oxide layer 302, thereby improving the reliability of the TFT 109.

Thereafter, as illustrated in FIG. 6C, a second protective insulating film 403 is deposited, and a transparent conductive thim film (ITO) is deposited. Then, the ITO is patterned in a predetermined configuration to form a common electrode 111. Thereafter, an interlayer insulating film 404 is deposited.

Thereafter, as illustrated in FIG. 6D, a second contact hole 303 is formed at the first and second protective insulating films 402 and 403 and the interlayer insulating film 404. Then, an ITO is deposited and patterned in a predetermined configuration to form a pixel electrode 110.

Note that in the above process, for example, a photolithography process is used to process a predetermined pattern such as a metal layer. The photolithography process includes resist coating, exposure using a mask, development, etching, and resist lift-off. Since the photolithography process is well-known, a detailed description thereof will be omitted herein.

According to the present embodiment, the source electrode is formed as a portion of the pixel electrode 110 which is formed on a layer that is different from the drain electrode, thereby promoting the high definition of a pixel. Specifically, for example, when the source electrode is formed of a metal layer, since a restriction based on the distance between adjacent drain lines 107 can be removed, the distance between adjacent two drain lines 107 can be reduced.

Also, according to the present embodiment, since the source electrode is formed by the pixel electrode 110, the source electrode formed of a metal layer can be excluded. Therefore, the aperture ratio of the pixel can be increased, thus making it possible to increase a luminance and reduce the power consumption of the backlight unit.

Note that, as compared to the related art, a gate-source parasitic capacitance (Cgs) can be reduced. Therefore, the gate line capacity can be reduced, a so-called kickback voltage to a display voltage can be reduced, and the display uniformity can be improved. Also, since the source electrode and the pixel electrode 110 are connected to the semiconductor oxide layer 302 through the first or second contact hole 301 or 303, an interface between the gate insulating film 401 and the semiconductor oxide layer 302 can be cleaned, and the threshold value non-uniformity of the TFT can be reduced, thus making it possible to improve the stability.

Also, the present invention is not limited to the above embodiment. For example, the configuration illustrated in the above embodiment may be substituted with any configuration exhibiting substantially the same effect, or any configuration capable of achieving the same object. Specifically, for example, various modifications may be possible as in the following modifications 1 to 3.

### [Modification 1]

Next, Modification 1 of the present invention will be described. Modification 1 is mainly different from the above embodiment in that a common signal line 701 is substantially parallel to a gate line 105 and an organic protection film 801 is provided on a first protective insulating film 402. In the following, a description of the same features as the above embodiment will be omitted.

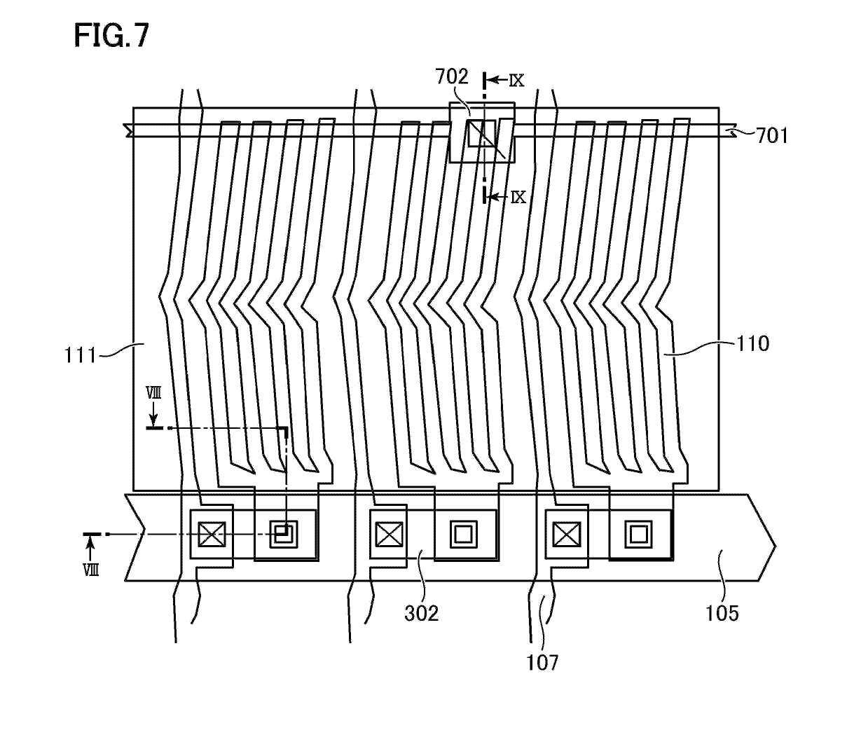

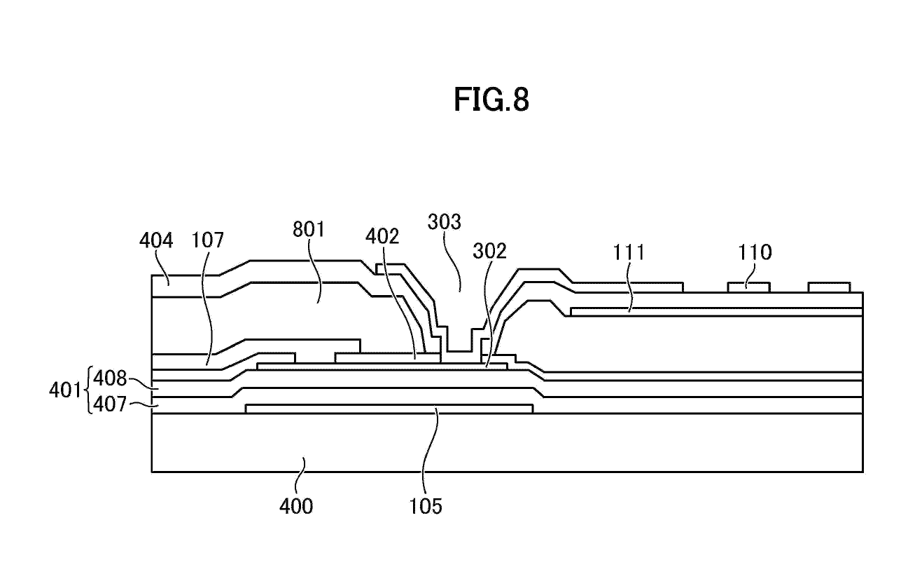

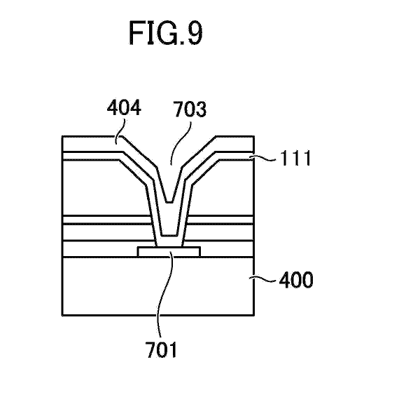

FIG. 7 is a diagram illustrating an example of a configuration of a pixel according to Modification 1. FIG. 8 illustrates a schematic example of a VIII-VIII section of FIG. 7, and FIG. 9 illustrates a schematic example of a IX-IX section of FIG. 7.

As illustrated in FIGS. 7 and 8, according to Modification 1, in a region in which a TFT 109 is formed, a substrate 400, a gate electrode formed as a portion of a gate line 105, a gate insulating film 401, a semiconductor oxide layer 302, an organic protection film 801, an interlayer insulating film 404, and a pixel electrode 110 are stacked sequentially from the bottom of FIG. 8.

Also, in a region in which a pixel is formed, a substrate 400, a gate insulating film 401, a semiconductor oxide layer 302, an organic protection film 801, a common electrode 111, an interlayer insulating film 404, and a pixel electrode 110 are stacked sequentially from the bottom of FIG. 7.

As in the above embodiment, the pixel electrode 110 is connected to the semiconductor oxide layer 302 through a second contact hole 303 formed on the semiconductor oxide layer 302. That is, a portion of the pixel electrode 110 corresponds to a source electrode of the TFT 109.

Also, in Modification 1, as illustrated in FIGS. 7 and 9, a common signal line 701 is provided to be substantially parallel to the gate line 105. The common signal line 701 is connected to the common electrode 111 through a third contact hole 703. Specifically, as illustrated in FIG. 9, the common signal line 701 is provided on the substrate 400. Also, it is connected to the common electrode 111 formed on the organic protection film 801, through the third contact hole 703 formed on the common signal line 701.

As in the above embodiment, in Modification 1, the pixel electrode 110 is connected to the semiconductor oxide layer 302 through the second contact hole 303 formed on the semiconductor oxide layer 302. That is, a portion of the pixel electrode 110 corresponds to a source electrode of the TFT 109. Therefore, as in the above embodiment, in Modification 1, the source electrode is formed as a portion of the pixel electrode 110 (ITO) formed on a different layer than the drain electrode, thereby promoting the high definition of the pixel.

### [Modification 2]

Next, Modification 2 of the present invention will be described. Modification 2 is mainly different from Modification 1 in that a contact portion between a semiconductor oxide layer 302 and a pixel electrode 110 is provided outside a gate electrode. In the following, a description of the same features as the above embodiment and Modification 1 will be omitted.

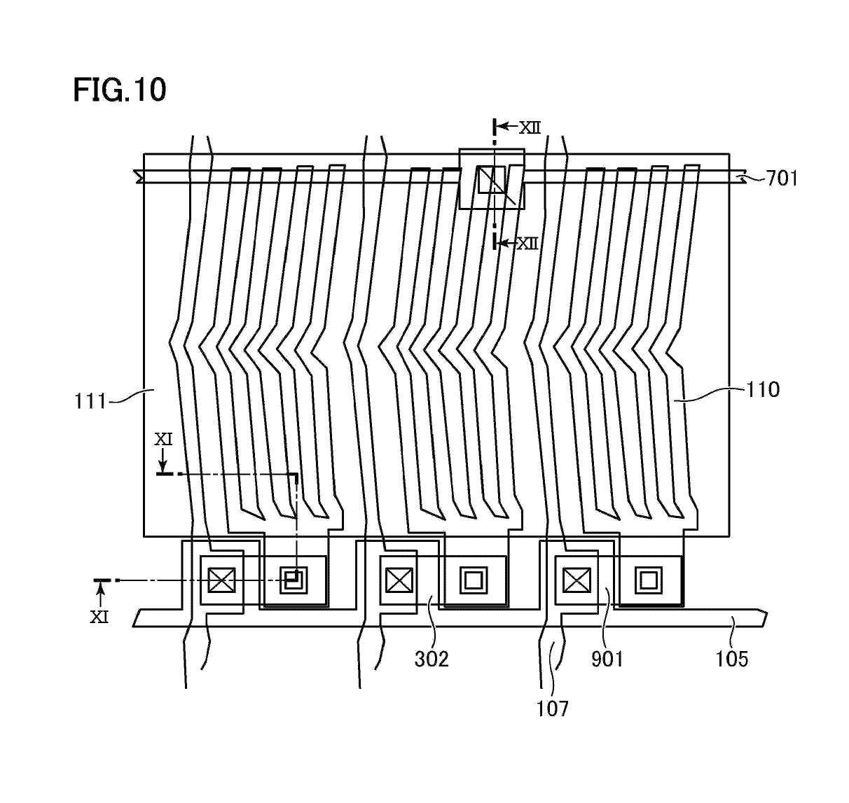

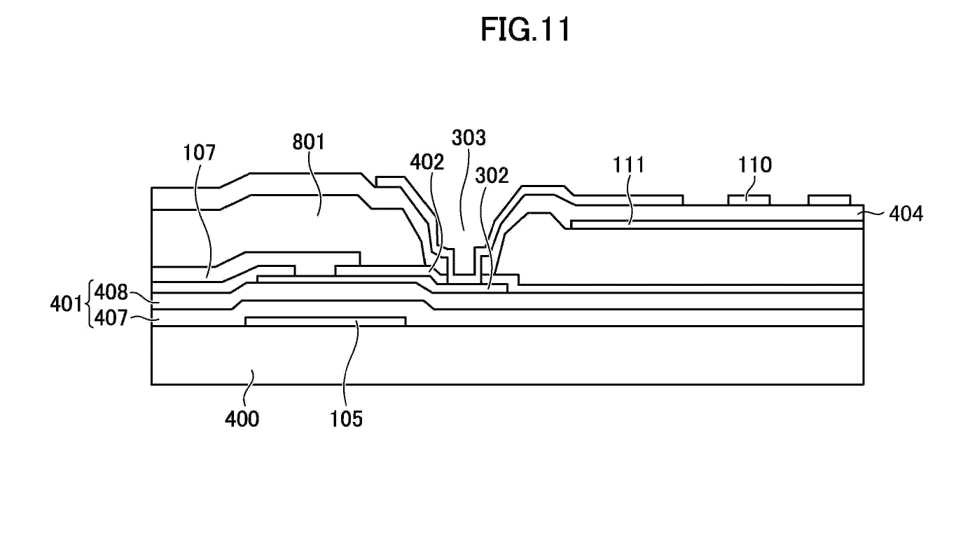

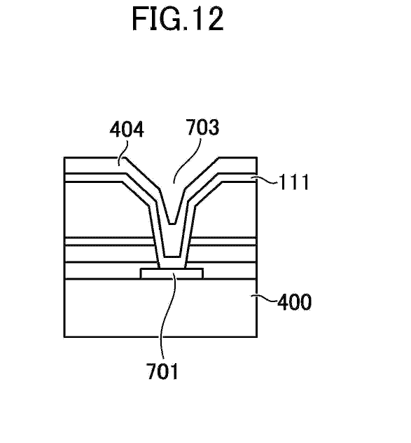

FIG. 10 is a diagram illustrating an example of a configuration of a pixel according to Modification 2. FIG. 11 illustrates a schematic example of a XI-XI section of FIG. 10, and FIG. 12 illustrates a schematic example of a XII-XII section of FIG. 10.

As illustrated in FIGS. 10 and 11, in Modification 2, a gate line 105 includes an extension portion 901, and at least a portion of the extension portion 901 forms a gate electrode. As illustrated in FIG. 11, the extension portion 901 has a smaller width than the semiconductor oxide layer 302. The pixel electrode 110 is connected through a second contact hole 303 to the semiconductor oxide layer 302 at a portion not overlapping with a gate electrode, that is, an outside portion of the gate electrode. Therefore, according to Modification 2, a gate-source capacitance (Cgs) can be reduced as compared to Modification 1. Note that since the XII-XII section of FIG. 10 is the same as Modification 1, a description thereof will be omitted herein.

Also, as in the above embodiment, in Modification 2, the pixel electrode 110 is connected to the semiconductor oxide layer 302 through a contact hole formed on the semiconductor oxide layer 302. That is, a portion of the pixel electrode 110 corresponds to a source electrode of the TFT 109. Therefore, as in the above embodiment, in Modification 2, the source electrode is formed as a portion of the pixel electrode 110 (ITO) formed on a different layer than the drain electrode, thereby promoting the high definition of the pixel.

### [Modification 3]

Next, Modification 3 of the present invention will be described. Modification 3 is mainly different from the above embodiment in that a common signal line 701 is substantially parallel to a gate line 105, a common electrode 111 is provided on a substrate 400, and a contact portion between a pixel electrode 110 and a semiconductor oxide layer 302 is provided outside a gate electrode. In the following, a description of the same features as the above embodiment will be omitted.

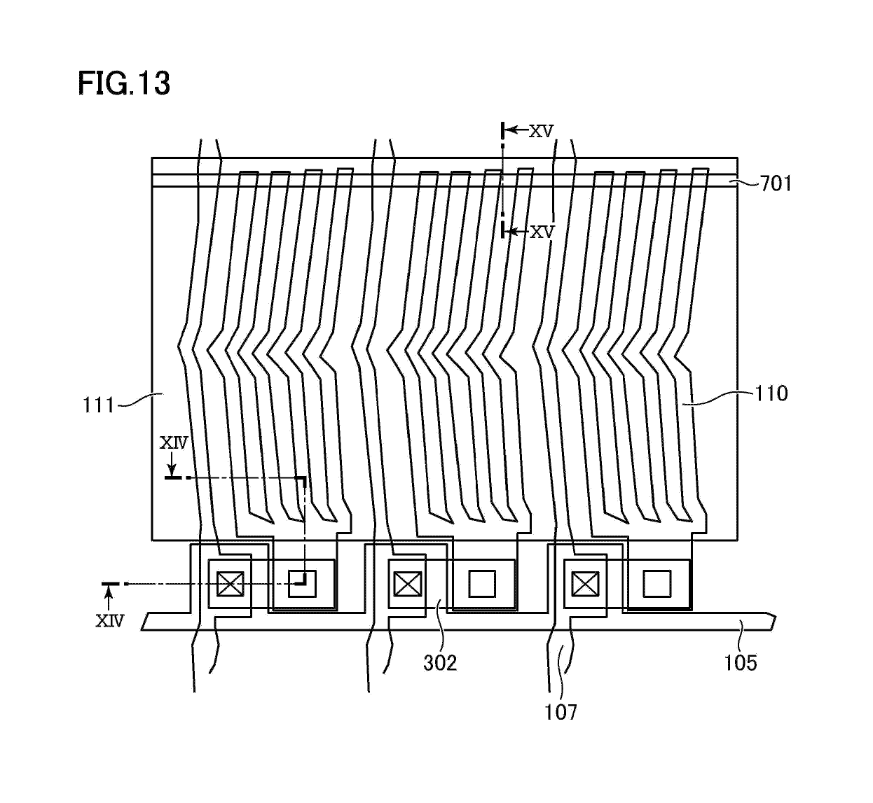

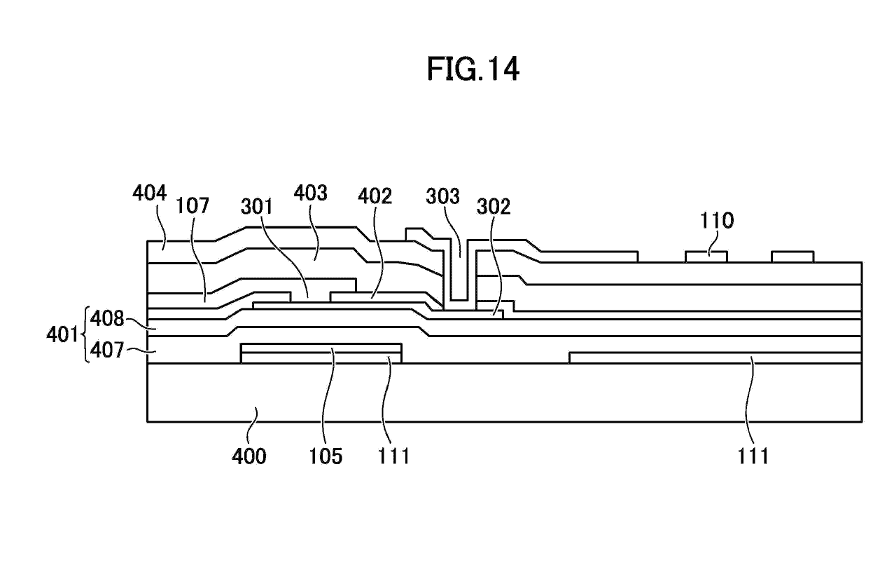

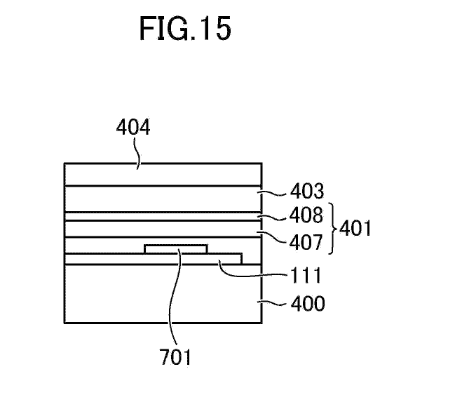

FIG. 13 is a diagram illustrating an example of a configuration of a pixel according to Modification 3. FIG. 14 illustrates a schematic example of a XIV-XIV section of FIG. 13, and FIG. 15 illustrates a schematic example of a XV-XV section of FIG. 13.

As illustrated in FIGS. 13 and 14, according to Modification 3, in a region in which a TFT 109 is formed, a substrate 400, a common electrode 111, a gate electrode formed as a portion of a gate line 105, a gate insulating film 401, a semiconductor oxide layer 302, a first protective insulating film 402, a second protective insulating film 403, an interlayer insulating film 404, and a pixel electrode 110 are stacked sequentially from the bottom of FIG. 14.

Also, first and second contact holes 301 and 303 are provided on the semiconductor oxide layer 302, and the semiconductor oxide layer 302 is connected through the first and second contact holes 301 and 303 to the drain electrode and the pixel electrode 110 formed on the first protective insulating film 402. Note that the drain electrode is formed as a portion of the drain line 107 as in the above embodiment.

As illustrated in FIG. 14, as in Modification 2, in Modification 3, the second contact hole 303 is provided on the semiconductor oxide layer 302 outside the gate electrode. Also, the second contact hole 303 is provided at the second protective insulating film 403 and the interlayer insulating film 404. Also, as in Modification 2, the gate electrode extends from, for example, the gate line 105, and the extension portion forms a gate electrode of the TFT 109.

As illustrated in FIG. 14, in a region in which a pixel is formed, a substrate 400, a common electrode 111, a gate insulating film 401, a first protective insulating film 402, a second protective insulating film 403, an interlayer insulating film 404, and a pixel electrode 110 are stacked sequentially from the bottom of FIG. 13.

Also, as illustrated in FIGS. 13 and 15, on the common electrode 111, a common signal line 701 is formed in a direction along the gate line 105.

As in the above embodiment, in Modification 3, the pixel electrode 110 is connected to the semiconductor oxide layer 302 through a contact hole formed on the semiconductor oxide layer 302. That is, a portion of the pixel electrode 110 corresponds to a source electrode of the TFT 109. Therefore, as in the above embodiment, in Modification 3, the source electrode is formed as a portion of the pixel electrode 110 formed on a different layer than the drain electrode, thereby promoting the high definition of the pixel.

The present invention is not limited to the above embodiment and Modifications 1 to 3. For example, the configurations illustrated in the above embodiment and Modifications 1 to 3 may be substituted with any configuration exhibiting substantially the same effect, or any configuration capable of achieving the same object.

For example, although a liquid crystal display apparatus has been described above, the present invention may also be applied to display apparatuses that use various light-emitting devices such as organic EL devices, inorganic EL devices, and field-emission devices (FEDs). Note that in the following claims, for example, a first insulating film corresponds to the first protective insulating film 402, a second insulating film corresponds to the second protective insulating film 403 or the organic protection film 801, and a third insulating film corresponds to the interlayer insulating film 404.

What is claimed is:

1. A display apparatus comprising:
a gate electrode formed on a substrate as a portion of a gate line;
a gate insulating film formed on the gate electrode;
a semiconductor oxide layer formed on the gate insulating film;
a first insulating film formed to cover the semiconductor oxide layer;
a drain electrode connected to the semiconductor oxide layer through a first contact hole that is formed at the first insulating film;
a second insulating film formed on the first insulating film;
a third insulating film formed on the second insulating film; and
a pixel electrode formed on the third insulating film,
wherein the pixel electrode is connected to the semiconductor oxide layer through a second contact hole that is formed on the semiconductor oxide layer.

2. The display apparatus according to claim 1, further comprising:
a common electrode positioned between the second insulating film and the third insulating film, in a region facing the pixel electrode.

3. The display apparatus according to claim 2, wherein the common electrode covers a drain line, comprising the drain electrode, through the second insulating film.

4. The display apparatus according to claim 1, wherein the second contact hole is formed at the first to third insulating films.

5. The display apparatus according to claim 1, wherein the second insulating film is an organic protection film.

6. The display apparatus according to claim 1, wherein the second contact hole is formed outside the gate electrode when viewing the display apparatus in a cross-sectional view.

7. The display apparatus according to claim 2, further comprising:
a common signal line in a portion between the substrate and the gate insulating film,
wherein the common signal line is connected to the common electrode through a third contact hole.

8. The display apparatus according to claim 1, further comprising:
a common electrode facing the pixel electrode, located between the substrate and the gate insulating film.

9. The display apparatus according to claim 8, further comprising:
a common signal line in a portion between the gate insulating film and the common electrode.

10. The display apparatus according to claim 7, wherein the common signal line is disposed in a direction along the gate line.

11. A method of manufacturing a display apparatus, comprising:
forming a gate electrode on a substrate as a portion of a gate line;
forming a gate insulating film on the gate electrode;
forming a semiconductor oxide layer on the gate insulating film;
forming a first insulating film so as to cover the semiconductor oxide layer;
forming a first contact hole at the first insulating film;
forming an electrode connected to the semiconductor oxide layer through the first contact hole;
forming a second insulating film on the first insulating film;
forming a third insulating film on the second insulating film;
forming a second contact hole on the semiconductor oxide layer; and
forming a pixel electrode on the third insulating film,
wherein the pixel electrode is connected to the semiconductor oxide layer through the second contact hole.

12. The display apparatus according to claim 1, wherein said gate electrode is in direct contact with said substrate.

13. The display apparatus according to claim 12, wherein said gate insulating film is in direct contact with said gate electrode.

14. The display apparatus according to claim 13, wherein said semiconductor oxide layer is in direct contact with said gate insulating film.

15. The display apparatus according to claim 14, wherein said first insulating film is in direct contact with said semiconductor oxide layer.

16. The display apparatus according to claim 15, wherein said second insulating film is in direct contact with said first insulating film.

17. The display apparatus according to claim 16, wherein said pixel electrode is in direct contact with said third insulating film.
